(19) United States
(12) Patent Application Publication
(10) Pub. No.: US 2009/0230433 A1
(43) Pub. Date: Sep. 17, 2009

(54) Nitride semiconductor device

(75) Inventor: Atsushi Yamaguchi, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/382,009

(22) Filed: Mar. 5, 2009

(30) Foreign Application Priority Data
Mar. 6, 2008 (JP) 2008-56750

(51) Int. Cl. H01L 29/20

(52) U.S. Cl. 257/201; 257/E29.089

(57) ABSTRACT

A nitride semiconductor device includes an n-type layer made of a group III nitride semiconductor and a layer made of a group III nitride semiconductor containing a p-type impurity laminated and formed in contact with the n-type layer, and Al is contained in a portion of the n-type layer in contact with the layer containing the p-type impurity.

### BACKGROUND OF THE INVENTION

1. Field of the Invention

The present invention relates to a nitride semiconductor device employing group III nitride semiconductors.

2. Description of Related Art

In general, a power device employing a silicon semiconductor is employed for a power amplifier circuit, a power supply circuit, a motor driving circuit or the like.

However, improvement in withstand voltage, reduction in resistance and improvement in speed of a silicon device are now reaching the limits due to the theoretical limit of the silicon semiconductor, and it is becoming difficult to satisfy requirements of the market.

Therefore, development of a nitride semiconductor device having characteristics such as a high withstand voltage, a high-temperature operation, a high current density, high-speed switching and small on-resistance is examined.

FIG. 8 is a schematic sectional view of a conventional nitride semiconductor device.

The nitride semiconductor device includes a sapphire substrate 81 and a multilayer structure portion 93 of an npn structure formed by an undoped GaN layer 82, an n-type GaN layer 83, a p-type GaN layer 84 and an n-type GaN layer 85 successively laminated on the sapphire substrate 81.

A mesa multilayer portion 92 having a mesa shape is formed in the multilayer structure portion 93 by etching the same from the surface of the n-type GaN layer 85 up to an intermediate portion of the n-type GaN layer 83. Both side surfaces of the mesa multilayer portion 92 are inclined surfaces 91 inclined with respect to laminating interfaces of the multilayer structure portion 93. A gate insulating film 86 made of SiO₂ (silicon oxide) is formed on the surface of the multilayer structure portion 93 (including the inclined surfaces 91).

Contact openings partially exposing the n-type GaN layers 85 and 83 respectively are formed in the gate insulating film 86. A source electrode 88 is formed on the n-type GaN layer 85 exposed from the corresponding contact opening, to be in ohmic contact with the n-type GaN layer 85. On the other hand, drain electrodes 89 are formed on the n-type GaN layer 83 exposed from the corresponding contact openings, to be in ohmic contact with the n-type GaN layer 83. Gate electrodes 87 are formed on portions of the gate insulating film 86 opposed to the inclined surfaces 91. Interlayer dielectric films 90 made of polyimide are interposed between adjacent ones of the source electrode 88, the drain electrodes 89 and the gate electrodes 87, to isolate the source electrode 88, the drain electrodes 89 and the gate electrodes 87 from one another.

The n-type GaN layer 83, the p-type GaN layer 84 and the n-type GaN layer 85 comprising the vertical npn structure shown in FIG. 8 are formed by growing GaN by MOCVD (Metal Organic Chemical Vapor Deposition), for example.

In the formation of each GaN layer 83, 84 or 85, the grown GaN is doped with an impurity (an n-type impurity: Si (silicon) or a p-type impurity: Mg (magnesium), for example) corresponding to each conductivity type, to have the conductivity type corresponding to each GaN layer 83, 84 or 85.

In order to convert the grown GaN to a p-type, GaN needs to be doped with Mg in a high impurity concentration. For example, GaN needs to be doped with Mg in an impurity concentration of not less than 4×10¹⁹ cm⁻³, for example.

When GaN comprising the p-type GaN layer 84 is doped with Mg in the aforementioned impurity concentration in the process of the growth thereof, however, Mg may diffuse into the n-type GaN layer 83. Consequently, no excellent p-n junction is formed between the n-type GaN layer 83 and the p-type GaN layer 84, and a leakage current is disadvantageously generated in operation of the device. In the process of the growth of GaN comprising the n-type GaN layer 85 after the formation of the p-type GaN layer 84, Mg contained in the p-type GaN layer 84 may diffuse into the GaN to increase the resistance of the n-type GaN layer 85.

### SUMMARY OF THE INVENTION

An object of the present invention is to provide a nitride semiconductor device having a structure capable of inhibiting a p-type impurity from diffusing into an n-type semiconductor layer made of a group III nitride semiconductor.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic sectional view of a nitride semiconductor device according to a first embodiment of the present invention.

FIGS. 2A to 2H are schematic sectional views for illustrating a method of manufacturing the nitride semiconductor device shown in FIG. 1.

FIG. 3A is a profile for illustrating concentration distribution of Mg contained in an n⁻-type GaN layer, an n⁻-type AlGaN layer and a p-type GaN layer shown in FIG. 1.

FIG. 3B is a profile for illustrating concentration distribution of Mg contained in an n-type GaN layer and a p-type GaN layer on the side of a sapphire substrate shown in FIG. 8.

FIG. 4 is a schematic sectional view of a nitride semiconductor device according to a second embodiment of the present invention.

FIGS. 5A to 5H are schematic sectional views for illustrating a method of manufacturing the nitride semiconductor device shown in FIG. 4.

FIG. 6A is a profile for illustrating concentration distribution of Mg contained in a p-type GaN layer, an n⁻-type AlGaN layer and an n⁺-type GaN layer shown in FIG. 4.

FIG. 6B is a profile for illustrating concentration distribution of Mg contained in the p-type GaN layer and an n-type GaN layer on the side of a source electrode shown in FIG. 8.

FIG. 7 is a schematic sectional view of a nitride semiconductor device according to a third embodiment of the present invention.

FIG. 8 is a schematic sectional view of a conventional nitride semiconductor device.

### DETAILED DESCRIPTION OF THE INVENTION

A nitride semiconductor device according to an embodiment of the present invention includes an n-type layer made of a group III nitride semiconductor and a layer made of a group III nitride semiconductor containing a p-type impurity laminated and formed in contact with the n-type layer, and Al is contained in a portion of the n-type layer in contact with the layer containing the p-type impurity.

A diffusion rate of a p-type impurity with respect to a group III nitride semiconductor containing Al is slow as compared with a diffusion rate with respect to a group III nitride semiconductor containing no Al. Therefore, the p-type impurity can be inhibited from diffusing into the n-type layer due to Al contained in the portion of the n-type layer in contact with the layer containing the p-type impurity, even if the layer containing the p-type impurity is doped with the p-type impurity in a high impurity concentration.

The n-type layer may be prepared by laminating an Al-containing layer containing Al formed in contact with the layer containing the p-type impurity and an Al-free layer containing no Al laminated and formed on the Al-containing layer.

A nitride semiconductor device according to another embodiment of the present invention includes a first layer made of an n-type group III nitride semiconductor, a second layer made of a group III nitride semiconductor containing a p-type impurity laminated and formed in contact with the first layer and a third layer made of an n-type group III nitride semiconductor laminated and formed on the second layer, and Al is contained in a portion of the first layer in contact with the second layer.

According to the structure, Al is contained in the portion of the first layer in contact with the second layer, whereby the p-type impurity can be inhibited from diffusing into the first layer even if the second layer is doped with the p-type impurity in a high impurity concentration. Consequently, an excellent p-n junction can be formed between the first layer and the second layer, and generation of a leakage current in operation of the device can be suppressed.

The nitride semiconductor device can be manufactured by a manufacturing method including the steps of forming the first layer by growing the group III nitride semiconductor containing Al, forming the second layer by growing the group III nitride semiconductor on the first layer and forming the third layer by growing the group III nitride semiconductor on the second layer by epitaxy such as MOCVD (Metal Organic Chemical Vapor Deposition), gas source MBE (Molecular Beam Epitaxy), or the like. In this case, Al is contained in the portion of the first layer in contact with the second layer, whereby the p-type impurity can be inhibited from diffusing into the first layer in the process of growing the group III nitride semiconductor comprising the second layer.

The first layer may be prepared by laminating an Al-containing layer containing Al formed in contact with the second layer and an Al-free layer containing no Al laminated and formed on the Al-containing layer, for example.

A nitride semiconductor device according to still another embodiment of the present invention includes a first layer made of an n-type group III nitride semiconductor, a second layer made of a group III nitride semiconductor containing a p-type impurity laminated and formed on the first layer and a third layer made of an n-type group III nitride semiconductor laminated and formed in contact with the second layer, and Al is contained in a portion of the third layer in contact with the second layer.

According to the structure, Al is contained in the portion of the third layer in contact with the second layer, whereby the p-type impurity can be inhibited from diffusing into the third layer even if the second layer is doped with the p-type impurity in a high impurity concentration. Consequently, increase in the resistance of the third layer can be suppressed.

The nitride semiconductor device can be manufactured by a manufacturing method including the steps of forming the first layer by growing the group III nitride semiconductor, forming the second layer by growing the group III nitride semiconductor on the first layer and forming the third layer by growing the group III nitride semiconductor containing Al on the second layer by the aforementioned epitaxy, for example. In this case, the third layer is formed by growing the group III nitride semiconductor containing Al, whereby the p-type impurity contained in the second layer can be inhibited from diffusing into the group III nitride semiconductor in the process of growing the group III nitride semiconductor.

The third layer may be prepared by laminating an Al-containing layer containing Al formed in contact with the second layer and an Al-free layer containing no Al laminated and formed on the Al-containing layer, for example.

A nitride semiconductor device according to a further embodiment of the present invention includes a first layer made of an n-type group III nitride semiconductor, a second layer made of a group III nitride semiconductor containing a p-type impurity laminated and formed in contact with the first layer and a third layer made of an n-type group III nitride semiconductor laminated and formed in contact with the second layer, and Al is contained in portions of the first layer and the third layer in contact with the second layer.

According to the structure, Al is contained in the portions of the first layer and the third layer in contact with the second layer respectively, whereby the p-type impurity can be inhibited from diffusing into the first and third layers even if the second layer is doped with the p-type impurity in a high impurity concentration. Consequently, generation of a leakage current can be suppressed by forming a steep p-n junction between the first layer and the second layer, and increase in the resistance of the third layer can be suppressed.

The embodiments of the present invention are now described in more detail with reference to the attached drawings.

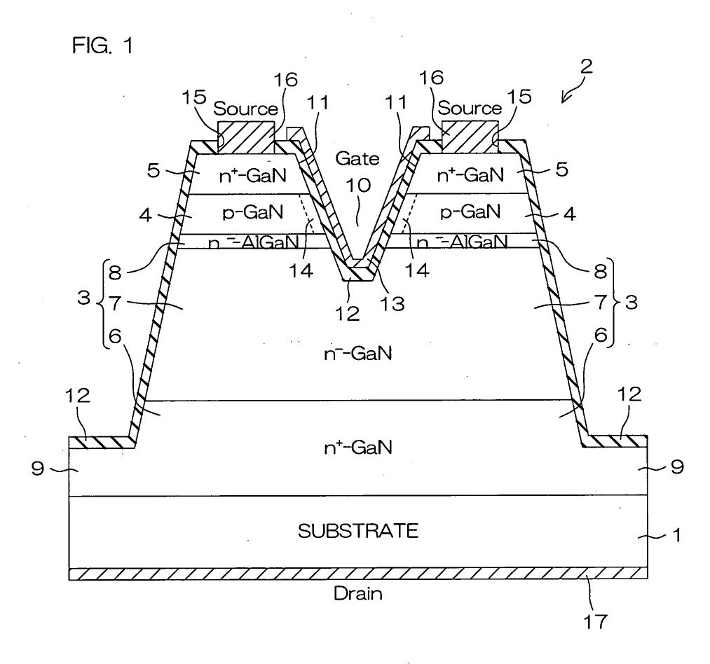

FIG. 1 is a schematic sectional view of a nitride semiconductor device according to a first embodiment of the present invention.

The nitride semiconductor device includes a substrate 1 and a nitride semiconductor multilayer structure portion 2 formed on one side of the substrate 1.

Preferably, a conductive substrate such as a nitride semiconductor substrate (a GaN substrate or an AlN substrate, for example) expressed as AlₓIn_{y}Ga_{1-x-y}N (0≦x≦1, 0≦y≦1 and 0≦x+y≦1), an SiC substrate or an Si substrate is applied as the substrate 1, for example.

The nitride semiconductor multilayer structure portion 2 includes an n-type layered portion 3 (first layer), a p-type GaN layer 4 (second layer) laminated and formed on the n-type layered portion 3 and an n⁺-type GaN layer 5 (third layer) laminated and formed on the p-type GaN layer 4.

The n-type layered portion 3 includes an n⁺-type GaN layer 6 formed on one surface (upper surface) of the substrate 1, an n⁻-type GaN layer 7 laminated and formed on the n⁺-type GaN layer 6 and an n⁻-type AlGaN layer 8 laminated and formed on the n⁻-type GaN layer 7.

The n⁺-type GaN layer 6 has an n-type impurity concentration of 1×10¹⁸ cm⁻³ to 1×10²⁰ cm⁻³, for example, higher than the n-type impurity concentrations in the n⁻-type GaN layer 7 and the n⁻-type AlGaN layer 8. On the other hand, the n-type impurity concentrations of the n⁻-type GaN layer 7 and the n⁻-type AlGaN layer 8 are 1'10¹⁶ cm⁻³ to 1×10¹⁷ cm⁻³, for example.

The n⁻-type AlGaN layer 8 forms the uppermost layer of the n-type layered portion 3, and the p-type GaN layer 4 is formed on the upper surface of the n⁻-type AlGaN layer 8 in contact with the n⁻-type AlGaN layer 8. According to the embodiment, the thickness of the overall n-type layered portion is 1 μm to 5 μm, and the thickness of the n⁻-type AlGaN layer 8 is 10 nm to 50 nm, for example. Preferably, the n⁻-type AlGaN layer 8 is expressed by a composition formula Al_{z}Ga_{1-z}N (0≦z≦1), and the value z showing the quantity of Al contained in the n⁻-type AlGaN layer 8 is 0.1 to 0.3.

The p-type impurity concentration in the p-type GaN layer 4 is 1×10¹⁸ cm⁻³ to 5×10¹⁹ cm⁻³, for example. The n-type impurity concentration in the n⁺-type GaN layer 5 is 1×10¹⁸ cm⁻³ to 1×10²⁰ cm⁻³, for example.

The nitride semiconductor multilayer structure portion 2 is etched in a direction across the laminating interfaces thereof from the n⁺-type GaN layer 5 up to a depth for exposing the n⁺-type GaN layer 6, to have a generally trapezoidal section. The n⁺-type GaN layer 6 has drawn portions 9 drawn in a lateral direction along the upper surface of the substrate 1 (the direction is hereinafter referred to as a “width direction”) from both sides of the nitride semiconductor multilayer structure portion 2. In other words, the drawn portions 9 are comprised of extensions of the n⁺-type GaN layer 6 according to the embodiment.

On the other hand, a trench 10 having a depth reaching an intermediate portion of the n⁻-type GaN layer 7 from the n⁺-type GaN layer 5 through the p-type GaN layer 4 and the n⁻-type AlGaN layer 8 is formed around an intermediate portion of the nitride semiconductor multilayer structure portion 2 in the width direction. According to the embodiment, the trench 10 has a generally V-shaped section, and inclined side surfaces thereof form wall surfaces 11 extending over the n⁻-type GaN layer 7, the n⁻-type AlGaN layer 8, the p-type GaN layer 4 and the n⁺-type GaN layer 5. A gate insulating film 12 covering the overall regions of the wall surfaces 11 is formed on the surfaces of the n⁺-type GaN layer 6, the n⁻-type GaN layer 7, the n⁻-type AlGaN layer 8, the p-type GaN layer 4 and the n⁺-type GaN layer 5.

The n⁺-type GaN layer 6, the n⁻-type GaN layer 7, the n⁻-type AlGaN layer 8, the p-type GaN layer 4 and the n⁺-type GaN layer 5 are epitaxially grown on the substrate 1 by MOCVD (Metal Organic Chemical Vapor Deposition), for example.

When the major surface of the substrate 1 is defined by a c-plane (0001), for example, the n⁺-type GaN layer 6, the n-type GaN layer 7, the n⁻-type AlGaN layer 8, the p-type GaN layer 4 and the n⁺-type GaN layer 5 epitaxially grown on the substrate 1 are laminated with major surfaces defined by c-planes (0001). The surface orientations of the wall surfaces 11 of the nitride semiconductor multilayer structure portion 2 are planes (other than c-planes) inclined in the range of 15° to 90° with respect to c-planes (0001), for example. More specifically, the wall surfaces 11 are defined by nonpolar planes such as m-planes (10-10) or a-planes (11-20) or semipolar planes such as (10-13), (10-11), (11-22), or the like.

The gate insulating film 12 can be comprised of a nitride or an oxide, for example. More specifically, the gate insulating film 12 can be comprised of SiN (silicon nitride), SiO₂ (silicon oxide) or a combination thereof. A gate electrode 13 is formed on the gate insulating film 12.

The gate electrode 13 is opposed to the wall surfaces 11, i.e., the n⁻-type GaN layer 7, the n⁻-type AlGaN layer 8, the p-type GaN layer 4 and the n⁺-type GaN layer 5 through the gate insulating film 12, and extends up to portions around edge portions of the trench 10 on the upper surface of the n⁺-type GaN layer 5. The gate electrode 13 can be comprised of a conductive material such as an Ni/Au alloy consisting of Ni and Au laminated thereon, a Pd/Au alloy, a Pd/Ti/Au alloy or a Pd/Pt/Au alloy, Pt, Al, polysilicon, or the like.

Regions of the p-type GaN layer 4 around the wall surfaces 11 are channel regions 14 opposed to the gate electrode 13. When a proper bias is supplied to the gate electrode 13, inversion channels electrically conducting the n-type layered portion 3 and the n⁺-type GaN layer 5 are formed in the channel regions 14.

Openings 15 partially exposing the upper surface of the n⁺-type GaN layer 5 are formed in the gate insulating film 12. Source electrodes 16 are formed on the n⁺-type GaN layer 5 exposed from the openings 15.

The source electrodes 16, in ohmic contact with the n⁺-type GaN layer 5, can be comprised of a metal such as a Ti/Al alloy comprising Ti and Al laminated thereon, for example. The source electrodes 16 are made of the metal containing Al, so that the same can be excellently brought into ohmic contact with the n⁺-type GaN layer 5. Alternatively, the source electrodes 16 may be comprised of Mo or an Mo compound (molybdenum silicide, for example), Ti or a Ti compound (titanium silicide, for example) or W or a W compound (tungsten silicide, for example).

A drain electrode 17 is formed in contact with the other surface (lower surface) of the substrate 1. The drain electrode 17, in ohmic contact with the substrate 1, can be comprised of the same metal as the source electrodes 16, i.e., a metal such as a Ti/Al alloy, for example. Alternatively, the drain electrode 17 may be comprised of Mo or an Mo compound (molybdenum silicide, for example), Ti or a Ti compound (titanium silicide, for example) or W or a W compound (tungsten silicide, for example).

Operation of the aforementioned nitride semiconductor device is now described.

A bias positive on the side of the drain electrode 17 is supplied between the source electrodes 16 and the drain electrode 17. Thus, a reverse voltage is supplied to a p-n junction on the interface between the n⁻-type AlGaN layer 8 and the p-type GaN layer 4, whereby the n⁺-type GaN layer 5 and the n-type layered portion 3, i.e., the source electrodes 16 and the drain electrode 17 (the source and the drain) are cut off (reverse-biased) as a result.

When a bias exceeding a gate threshold voltage positive with reference to the source electrodes 16 is applied to the gate electrode 13 from the state, electrons are induced around the interfaces between the channel regions 14 and the gate insulating film 12, to form inversion layers (channels).

The n-type layered portion 3 and the n⁺-type GaN layer 5 conduct through the inversion layers. Thus, the source and the drain conduct. In other words, the source and the drain conduct when a prescribed bias is supplied to the gate electrode 13, while the source and the drain are cut off when no bias is supplied to the gate electrode 13. Thus, normally-off operation is implemented.

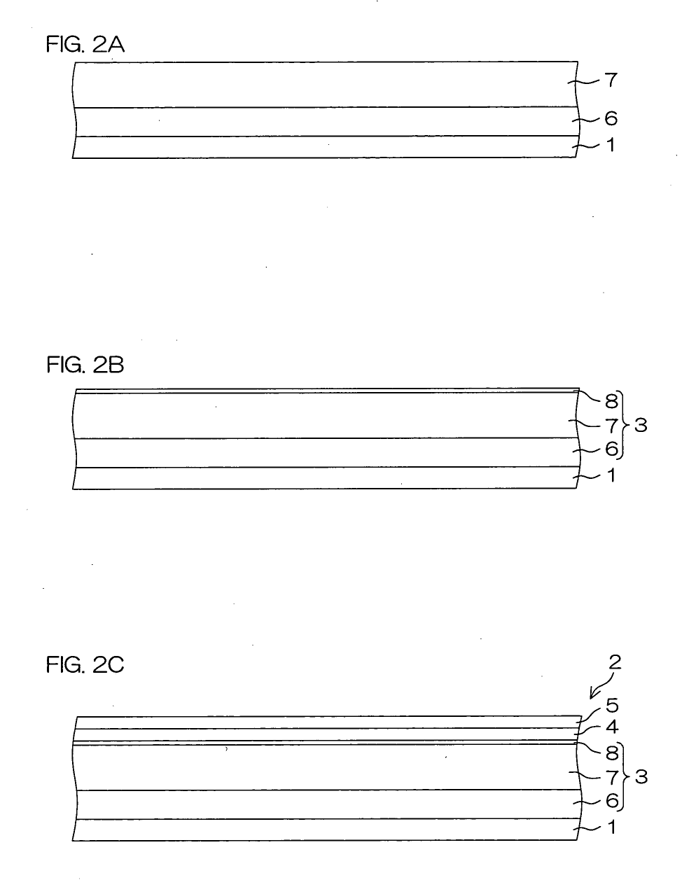

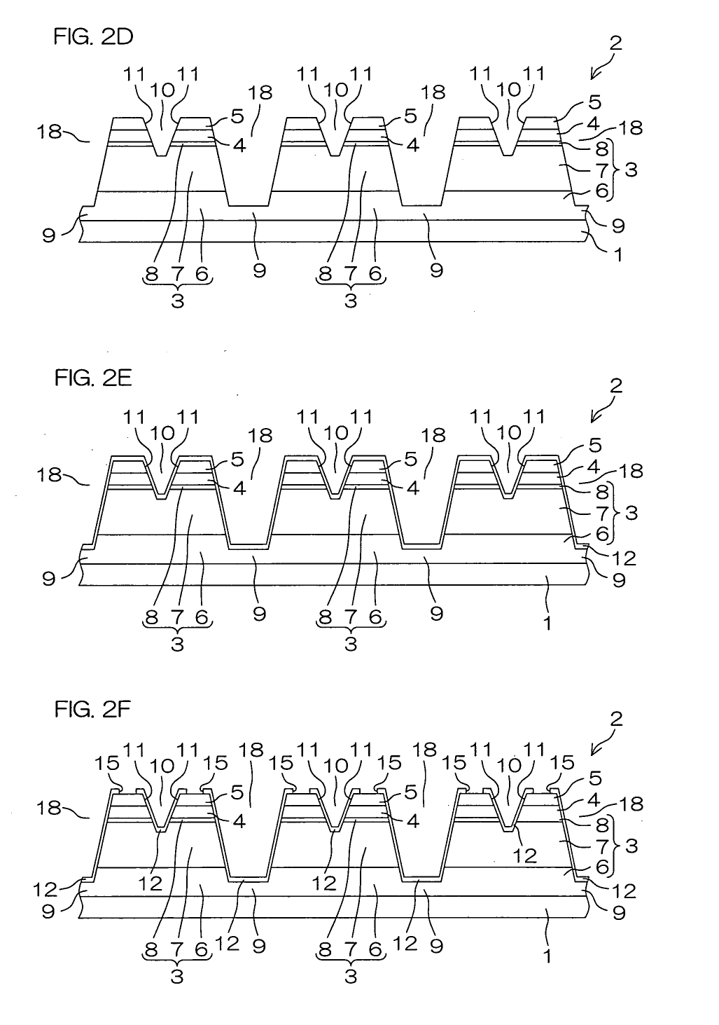

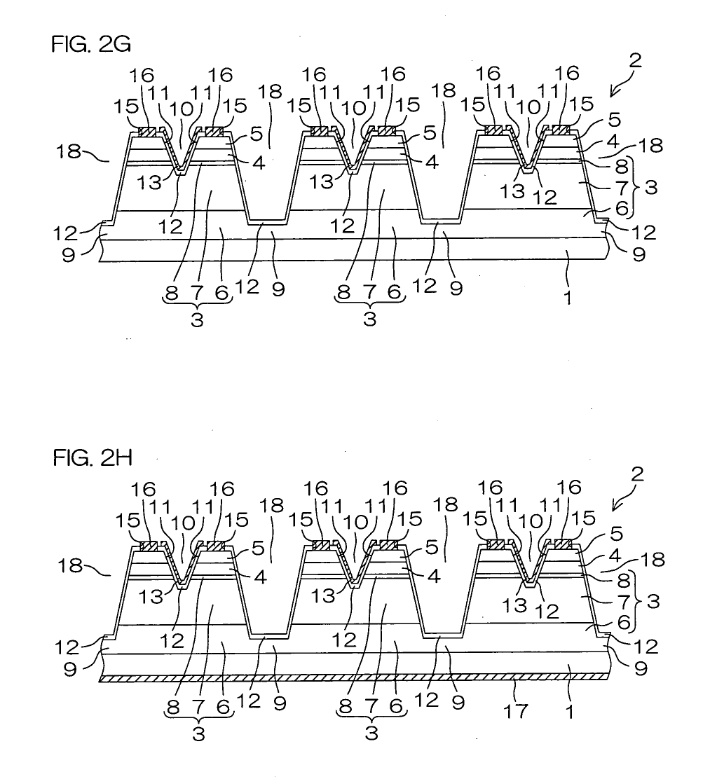

FIGS. 2A to 2H are schematic sectional views for illustrating a method of manufacturing the nitride semiconductor device shown in FIG. 1.

In order to manufacture the nitride semiconductor device, the substrate 1 is first prepared, and the n⁺-type GaN layer 6 and the n⁻-type GaN layer 7 are formed by growing GaN on the substrate 1 by MOCVD (Metal Organic Chemical Vapor Deposition) under growth conditions of a growth temperature of 1000° C. to 1100° C. and a growth time of 20 minutes to 30 minutes, for example, as shown in FIG. 2A. Si, for example, can be employed as an n-type impurity for doping the grown GaN.

After the formation of the n⁺-type GaN layer 6 and the n⁻-type GaN layer 7, the n⁻-type AlGaN layer 8 is formed by growing AlGaN on the n⁻-type GaN layer 7 under growth conditions of a growth temperature of 1000° C. to 1100° C. and a growth time of 2 minutes to 20 minutes, for example, as shown in FIG. 2B. Thus, the n-type layered portion 3 consisting of the n⁺-type GaN layer 6, the n⁻-type GaN layer 7 and the n⁻-type AlGaN layer 8 is formed. Si, for example, can be employed as an n-type impurity for doping the grown AlGaN.

Following the formation of the n⁻-type AlGaN layer 8, the p-type GaN layer 4 is formed by growing GaN on the n⁻-type AlGaN layer 8 under growth conditions of a growth temperature of 950° C. to 1050° C. and a growth time of 30 minutes to 50 minutes, for example, as shown in FIG. 2C. Mg or Zn, for example, can be employed as a p-type impurity for doping the grown GaN, and Mg is employed in the embodiment. After the formation of the p-type GaN layer 4, the n⁺-type GaN layer 5 is formed by growing GaN under growth conditions of a growth temperature of 1000° C. to 1100° C. and a growth time of 5 minutes to 15 minutes, for example, as shown in FIG. 2C. Si, for example, can be employed as an n-type impurity for doping the grown GaN. Thus, the nitride semiconductor multilayer structure portion 2 consisting of the n⁺-type GaN layer 6, the n⁻-type GaN layer 7, the n⁻-type AlGaN layer 8, the p-type GaN layer 4 and the n⁺-type GaN layer 5 is formed on one side of the substrate 1.

After the formation of the nitride semiconductor multilayer structure portion 2, the nitride semiconductor multilayer structure portion 2 is etched in a striped manner. In other words, trenches 18, having sections generally in the form of inverted trapezoids, reaching layer-thickness intermediate portions of the n⁻-type GaN layer 6 from the n⁺-type GaN layer 5 are formed by etching. Thus, a plurality of (three in the embodiment) nitride semiconductor multilayer structure portions 2 are shaped in a striped manner, and the drawn portions 9 consisting of extensions of the n⁻-type GaN layer 6 are formed at the same time, as shown in FIG. 2D. The trenches 18 can be formed by dry etching (anisotropic etching) employing chlorine-based gas, for example.

The trench 10 having the generally V-shaped section is formed around the intermediate portion of each nitride semiconductor multilayer structure portion 2 in the width direction along the longitudinal direction of the nitride semiconductor multilayer structure portion 2. The trench 10 can be formed by dry etching (anisotropic etching) employing chlorine-based gas, similarly to the trenches 18. After the dry etching, wet etching may be performed for improving the wall surfaces 11 of the trench 10 damaged by the dry etching, if necessary.

Preferably, KOH (potassium hydroxide) or NaOH (sodium hydroxide) is employed for the wet etching. Thus, the damaged wall surfaces 11 can be improved, and less-damaged wall surfaces 11 can be obtained. An Si-based oxide and an oxide of Ga can be removed also by wet etching with HF (hydrofluoric acid) or HCl (hydrochloric acid), so that the wall surfaces 11 can be leveled and less-damaged wall surfaces 11 can be obtained. Damage on the wall surfaces 11 is so reduced that the channel regions 14 (see FIG. 1) can be kept in excellent crystal states and excellent interfaces can be formed between the wall surfaces 11 and the gate insulating film 12, whereby interfacial levels can be reduced. Thus, channel resistance can be reduced, and a leakage current can be suppressed. Low-damage dry etching can be applied in place of the wet etching.

Then, the gate insulating film 12 covering the wall surfaces 11 of the generally V-shaped trench 10 as well as the surfaces of the n⁺-type GaN layer 6, the n⁻-type GaN layer 7, the n⁻-type AlGaN layer 8, the p-type GaN layer 4 and the n⁺-type GaN layer 5 is formed, as shown in FIG. 2E. Preferably, ECR (Electron Cyclotron Resonance) sputtering is applied to the formation of the gate insulating film 12.

Thereafter the gate insulating film 12 is dry-etched in a striped manner through a photoresist film (not shown) having openings in regions for forming the openings 15 by well-known photolithography. Thus, the openings 15 are formed to partially expose the n⁺-type GaN layer 5, as shown in FIG. 2F.

Then, metals (Ti and Al, for example) employed as the materials for the source electrodes 16 are sputtered in order of Ti and Al through a photoresist film (not shown) having openings in regions for forming the source electrodes 16 by well-known photolithography. Thereafter the photoresist film is removed, so that unnecessary portions (portions other than the source electrodes 16) of the metals are lifted off along with the photoresist film. The source electrodes 16 are formed through these steps, as shown in FIG. 2G. After the formation of the source electrodes 16, thermal alloying (annealing) is performed, so that the source electrodes 16 are in ohmic contact with the n⁺-type GaN layer 5.

Thereafter the gate electrode 13 opposed to the edge portions of the trench 10 on the wall surfaces 11 and the upper surface of the n⁺-type GaN layer 5 through the gate insulating film 12 is formed by a method similar to that for the source electrodes 16, as shown in FIG. 2G.

Then, the drain electrode 17 is formed on the other surface (lower surface) of the substrate 1 by a method similar to that for the source electrodes 16, as shown in FIG. 2H. Thus, the nitride semiconductor device shown in FIG. 1 can be obtained.

The plurality of nitride semiconductor multilayer structure portions 2 form unit cells respectively. The gate electrodes 13 and the source electrodes 16 of the nitride semiconductor multilayer structure portions 2 are connected in common on unshown positions respectively. The drain electrode 17 is formed in contact with the substrate 1, and common to all cells.

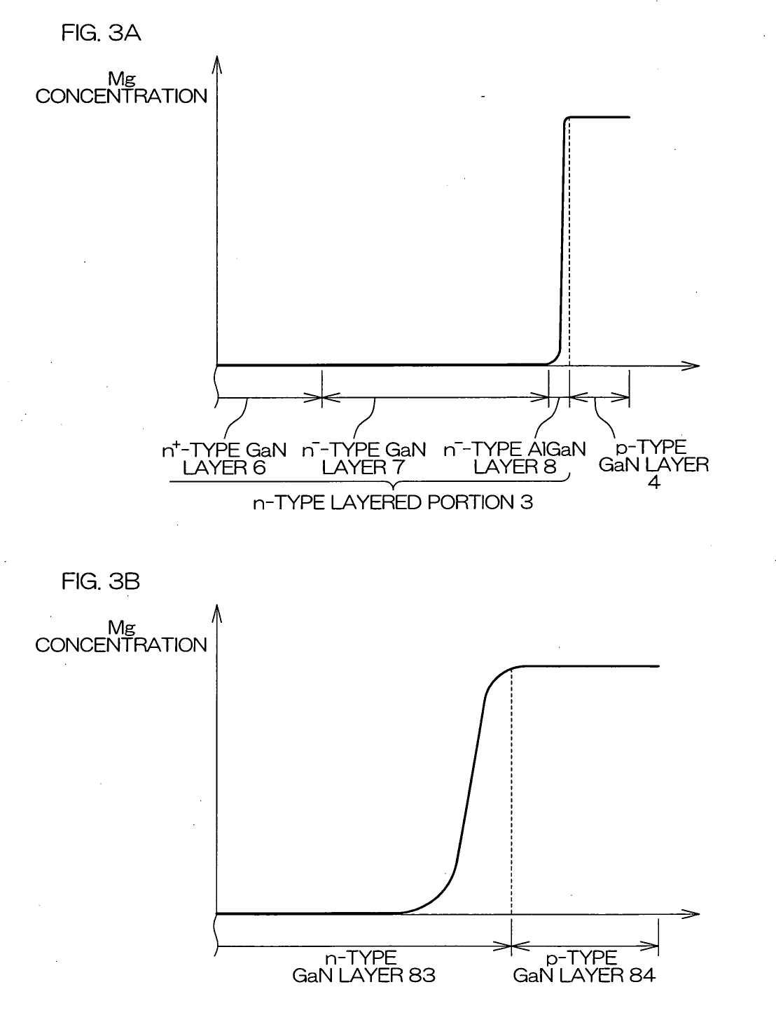

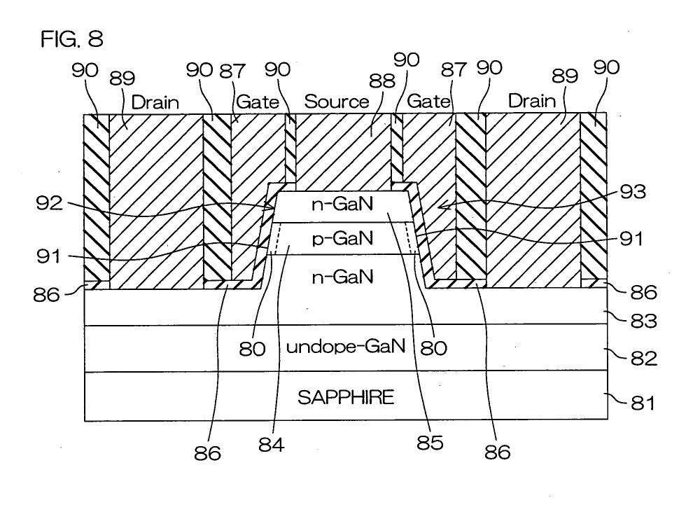

FIG. 3A is a profile for showing the concentration distribution of Mg contained in the n⁻-type GaN layer 7, the n⁻-type AlGaN layer 8 and the p-type GaN layer 4 shown in FIG. 1. FIG. 3B is a profile for showing the concentration distribution of Mg contained in the n-type GaN layer 83 and the p-type GaN layer 84 shown in FIG. 8. Referring to FIGS. 3A and 3B, the axes of abscissas show positions of the devices in the thickness directions.

Referring to FIGS. 1 and 3A, the n⁻-type AlGaN layer 8 is formed on a portion of the n-type layered portion 3 in contact with the p-type GaN layer 4. A diffusion rate of Mg with respect to AlGaN is slow as compared with a diffusion rate with respect to GaN. Even if GaN comprising the p-type GaN layer 4 is doped with Mg in a high impurity concentration (1×10¹⁸ cm⁻³ to 5×10²⁰ cm⁻³, for example) in the process of the growth thereof, therefore, the Mg does not diffuse into the n⁻-type GaN layer 7, although the same slightly diffuses into the n⁻-type AlGaN layer 8. Therefore, the Mg concentration profile around the interface between the n-type layered portion 3 and the p-type GaN layer 4 can be steepened, as shown in FIG. 3A.

Referring to FIGS. 8 and 3B, on the other hand, Mg for doping GaN comprising the p-type GaN layer 84 diffuses into the n-type GaN layer 83 in the process of the growth of GaN in the conventional structure forming the p-type GaN layer 84 by growing GaN to be in contact with the n-type GaN layer 83. Therefore, the Mg concentration profile around the interface between the n-type GaN layer 83 and the p-type GaN layer 84 is dull, as shown in FIG. 3B.

Thus, the n⁻-type AlGaN layer 8 is formed on the portion of the n-type layered portion 3 in contact with the p-type GaN layer 4 in the nitride semiconductor device according to the embodiment, whereby Mg can be inhibited from diffusing into the overall n-type layered portion 3. Consequently, an excellent p-n junction can be formed between the n-type layered portion 3 and the p-type GaN layer 4, and generation of a leakage current can be suppressed in the operation of the device.

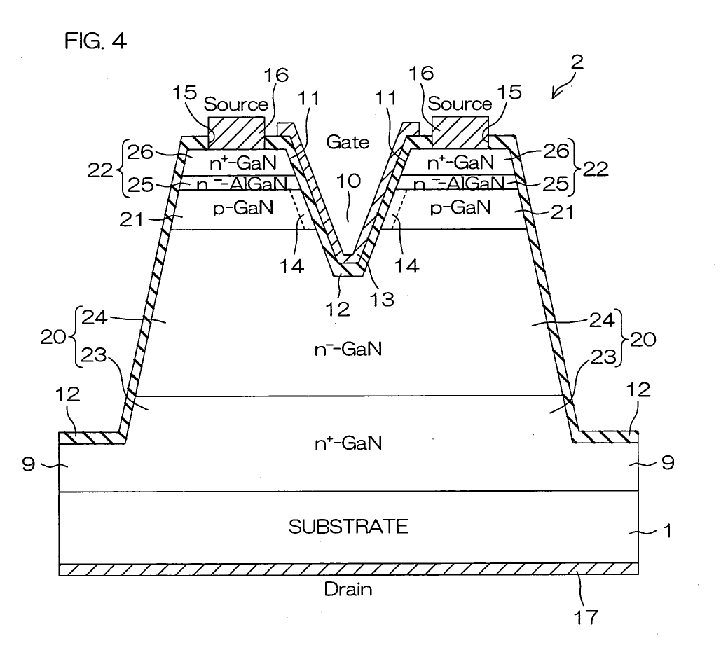

FIG. 4 is a schematic sectional view of a nitride semiconductor device according to a second embodiment of the present invention. Referring to FIG. 4, portions corresponding to those shown in FIG. 1 are denoted by the same reference numerals as those of the portions. Detailed description as to the portions denoted by the same reference numerals is omitted.

According to the embodiment, a nitride semiconductor multilayer structure portion 2 includes an n-type layered portion 20 (first layer), a p-type GaN layer 21 (second layer) laminated and formed on the n-type layered portion 20 and an n-type layered portion 22 (third layer) laminated and formed on the p-type GaN layer 21.

The h-type layered portion 20 includes an n⁺-type GaN layer 23 formed on one surface (upper surface) of a substrate 1 and an n⁻-type GaN layer 24 laminated and formed on the n⁺-type GaN layer 23.

The n⁺-type GaN layer 23 has an n-type impurity concentration of 1×10¹⁸ cm⁻³ to 1×10²⁰ cm⁻³, for example, higher than the n-type impurity concentration in the n⁻-type GaN layer 24. On the other hand, the n-type impurity concentration in the n⁻-type GaN layer 24 is 1×10¹⁶ cm⁻³ to 1×10¹⁷ cm⁻³, for example.

The p-type impurity concentration in the p-type GaN layer 21 is 1×10¹⁸ cm⁻³ to 5×10¹⁹ cm⁻³, for example.

The n-type layered portion 22 includes an n⁻-type AlGaN layer 25 formed in contact with the upper surface of the p-type GaN layer 21 and an n⁺-type GaN layer 26 laminated and formed on the n⁻-type AlGaN layer 25.

The n-type impurity concentration in the n⁺-type GaN layer 26 is 1×10¹⁸ cm⁻³ to 1×10²⁰ cm⁻³, for example. On the other hand, the n-type impurity concentration in the n⁻-type AlGaN layer 25 is 1×10¹⁸ cm⁻³ to 1×10²⁰ cm⁻³, for example.

According to the embodiment, the thickness of the overall n-type layered portion 22 is 1 μm to 5 μm, and the thickness of the n⁻-type AlGaN layer 25 is 10 nm to 50 nm, for example. Preferably, the n⁻-type AlGaN layer 25 is expressed by a composition formula Al_{z}Ga_{1-z}N (0≦z≦1), and the value z showing the quantity of Al contained in the n⁻-type AlGaN layer 25 is 0.1 to 0.3.

The nitride semiconductor multilayer structure portion 2 is etched in a direction across the laminating interfaces thereof from the n⁺-type GaN layer 26 up to a depth for exposing the n⁺-type GaN layer 23, to have a generally trapezoidal section. The n⁺-type GaN layer 23 has drawn portions 9 drawn in a width direction from both sides of the nitride semiconductor multilayer structure portion 2. In other words, the drawn portions 9 are comprised of extensions of the n⁺-type GaN layer 23 according to the embodiment.

A trench 10 is formed in a depth reaching an intermediate portion of the n⁻-type GaN layer 24 from the n⁺-type GaN layer 26 through the n⁻-type AlGaN layer 25 and the p-type GaN layer 21.

Wall surfaces 11 are formed to extend over the n⁻-type GaN layer 24, the p-type GaN layer 21, the n⁻-type AlGaN layer 25 and the n⁺-type GaN layer 26.

A gate electrode 13 is opposed to the wall surfaces 11, i.e., the n⁻-type GaN layer 24, the p-type GaN layer 21, the n⁻-type AlGaN layer 25 and the n⁺-type GaN layer 26 through a gate insulating film 12, and extends up to portions around edge portions of the trench 10 on the upper surface of the n⁺-type GaN layer 26.

Source electrodes 16 are in ohmic contact with the n⁺-type GaN layer 26. The remaining structure and operation of the second embodiment are similar to those of the aforementioned first embodiment.

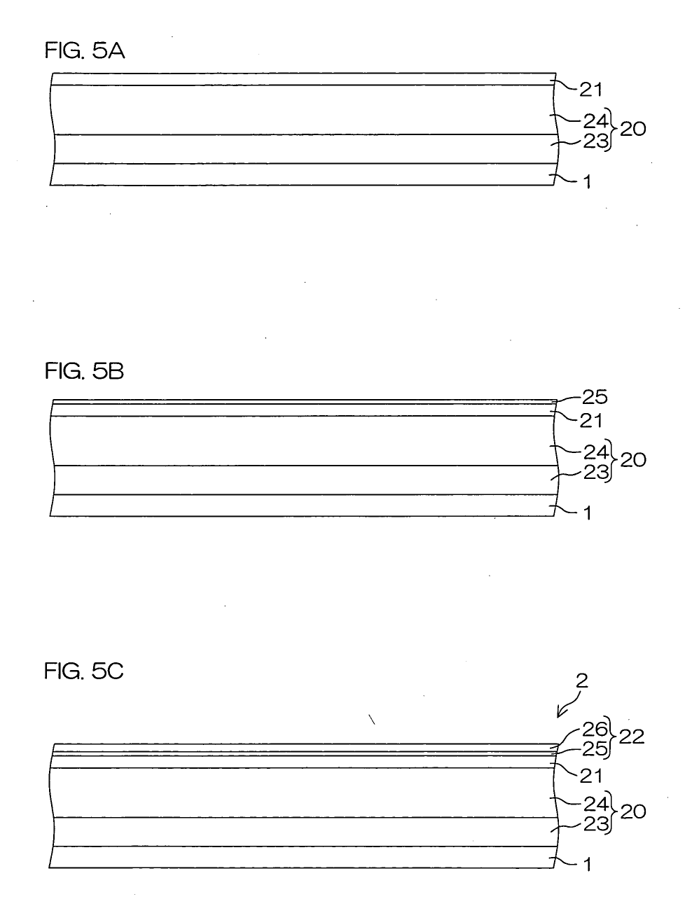

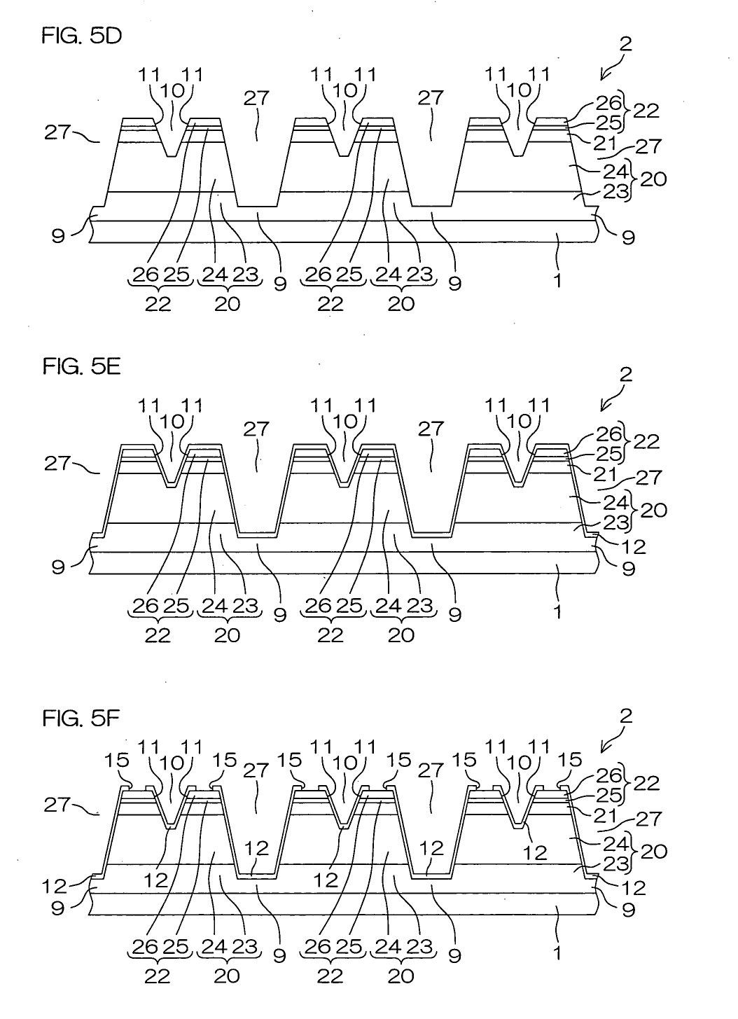

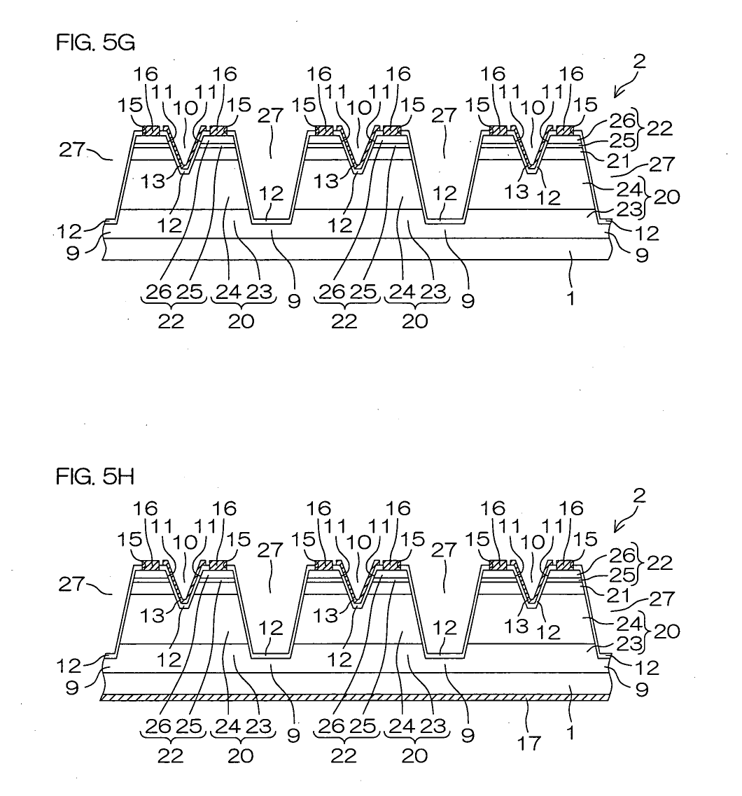

FIGS. 5A to 5H are schematic sectional views for illustrating a method of manufacturing the nitride semiconductor device shown in FIG. 4.

In order to manufacture the nitride semiconductor device, the substrate 1 is first prepared, and the n⁺-type GaN layer 23 and the n⁻-type GaN layer 24 are formed by growing GaN on the substrate 1 by MOCVD under growth conditions of a growth temperature of 1000° C. to 1100° C. and a growth time of 20 minutes to 30 minutes, for example, as shown in FIG. 5A. Si, for example, can be employed as an n-type impurity for doping the grown GaN. Thus, the n-type layered portion 20 is formed on one surface (upper surface) of the substrate 1. Then, the p-type GaN layer 21 is formed by growing GaN on the n⁻-type GaN layer 24 under growth conditions of a growth temperature of 950° C. to 1050° C. and a growth time of 30 minutes to 50 minutes, for example, as shown in FIG. 5A. Mg or Zn, for example, can be employed as a p-type impurity for doping the grown GaN, and Mg is employed in the embodiment.

Then, the n⁻-type AlGaN layer 25 is formed by growing AlGaN on the p-type GaN layer 21 under growth conditions of a growth temperature of 1000° C. to 1100° C. and a growth time of 2 minutes to 20 minutes, for example, as shown in FIG. 5B. Si, for example, can be employed as an n-type impurity for doping the grown AlGaN.

After the formation of the n⁻-type AlGaN layer 25, the n⁺-type GaN layer 26 is formed by growing GaN on the n⁻-type AlGaN layer 25 under growth conditions of a growth temperature of 1000° C. to 1100° C. and a growth time of 5 minutes to 15 minutes, for example, as shown in FIG. 5C. Si, for example, can be employed as an n-type impurity for doping the grown GaN. Thus, the n-type layered portion 22 consisting of the n⁻-type AlGaN layer 25 and the n⁺-type GaN layer 26 is formed, and the nitride semiconductor multilayer structure portion 2 consisting of the n-type layered portion 20, the p-type GaN layer 21 and the n-type layered portion 22 is formed on one side of the substrate 1.

After the formation of the nitride semiconductor multilayer structure portion 2, the nitride semiconductor multilayer structure portion 2 is etched in a striped manner. In other words, trenches 27, having sections generally in the form of inverted trapezoids, reaching layer-thickness intermediate portions of the n⁻-type GaN layer 23 from the n⁺-type GaN layer 26 are formed by etching. Thus, a plurality of (three in the embodiment) nitride semiconductor multilayer structure portions 2 are shaped in a striped manner, and the drawn portions 9 consisting of extensions of the n⁻-type GaN layer 23 are formed at the same time, as shown in FIG. 5D. The trenches 27 can be formed by dry etching (anisotropic etching) employing chlorine-based gas, for example.

The trench 10 having a generally V-shaped section is formed around an intermediate portion of each nitride semiconductor multilayer structure portion 2 in the width direction along the longitudinal direction of the nitride semiconductor multilayer structure portion 2. The trench 10 can be formed by dry etching (anisotropic etching) employing chlorine-based gas, similarly to the trenches 27. After the dry etching, wet etching may be performed for improving the wall surfaces 11 of the trench 10 damaged by the dry etching, if necessary.

Preferably, KOH (potassium hydroxide) or NaOH (sodium hydroxide) is employed for the wet etching. Thus, the damaged wall surfaces 11 can be improved, and less-damaged wall surfaces 11 can be obtained. An Si-based oxide and an oxide of Ga can be removed also by wet etching with HF (hydrofluoric acid) or HCl (hydrochloric acid), so that the wall surfaces 11 can be leveled and less-damaged wall surfaces 11 can be obtained. Damage on the wall surfaces 11 is so reduced that channel regions 14 (see FIG. 4) can be kept in excellent crystal states and excellent interfaces can be formed between the wall surfaces 11 and the gate insulating film 12, whereby interfacial levels can be reduced. Thus, channel resistance can be reduced, and a leakage current can be suppressed. Low-damage dry etching can be applied in place of the wet etching.

Then, the gate insulating film 12 covering the wall surfaces 11 of the generally V-shaped trench 10 as well as the surfaces of the n⁺-type GaN layer 23, the n⁻-type GaN layer 24, the p-type GaN layer 21, the n⁻-type AlGaN layer 25 and the n⁺-type GaN layer 26 is formed, as shown in FIG. 5E. Preferably, ECR (Electron Cyclotron Resonance) sputtering is preferably applied to the formation of the gate insulating film 12.

Thereafter the gate insulating film 12 is dry-etched in a striped manner through a photoresist film (not shown) having openings in regions for forming openings 15 by well-known photolithography. Thus, the openings 15 are formed to partially expose the n⁺-type GaN layer 26, as shown in FIG. 5F.

Then, metals (Ti and Al, for example) employed as the materials for the source electrodes 16 are sputtered in order of Ti and Al through a photoresist film (not shown) having openings in regions for forming the source electrodes 16 by well-known photolithography. Thereafter the photoresist film is removed, so that unnecessary portions (portions other than the source electrodes 16) of the metals are lifted off along with the photoresist film. The source electrodes 16 are formed through these steps, as shown in FIG. 5G. After the formation of the source electrodes 16, thermal alloying (annealing) is performed, so that the source electrodes 16 are in ohmic contact with the n⁺-type GaN layer 26.

Thereafter the gate electrode 13 opposed to the edge portions of the trench 10 on the wall surfaces 11 and the upper surface of the n⁺-type GaN layer 26 through the gate insulating film 12 is formed by a method similar to that for the source electrodes 16, as shown in FIG. 5G.

Then, a drain electrode 17 is formed on the other surface (lower surface) of the substrate 1 by a method similar to that for the source electrodes 16, as shown in FIG. 5H. Thus, the nitride semiconductor device shown in FIG. 4 can be obtained.

The plurality of nitride semiconductor multilayer structure portions 2 form unit cells respectively. The gate electrodes 13 and the source electrodes 16 of the nitride semiconductor multilayer structure portions 2 are connected in common on unshown positions respectively. The drain electrode 17 is formed in contact with the substrate 1, and common to all cells.

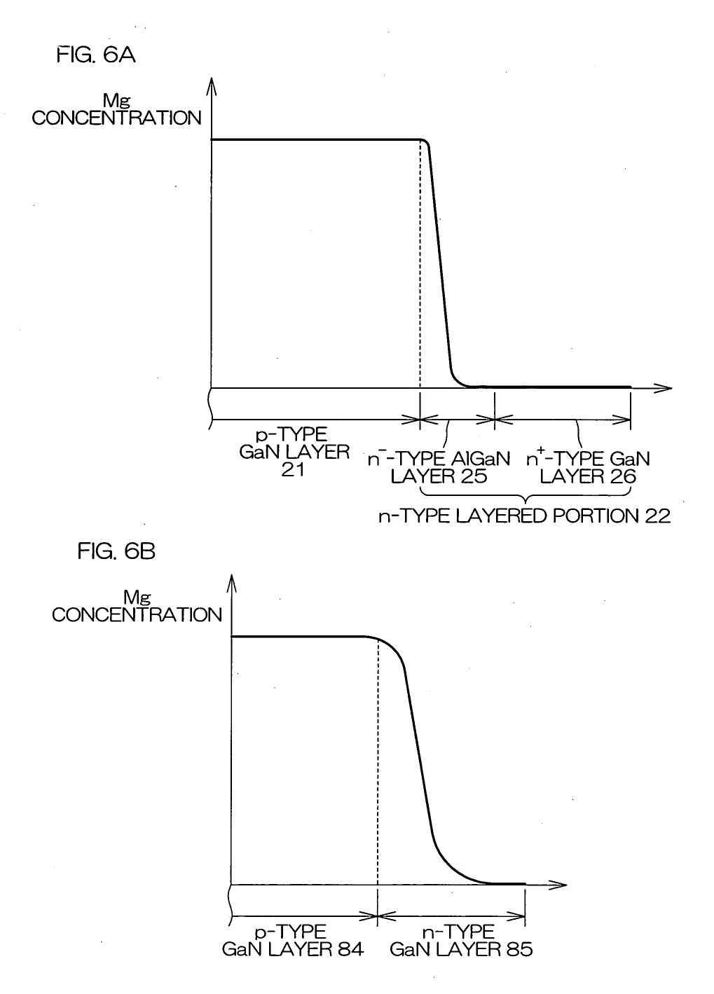

FIG. 6A is a profile for showing the concentration distribution of Mg contained in the p-type GaN layer 21, the n⁻-type AlGaN layer 25 and the n⁺-type GaN layer 26 shown in FIG. 4. FIG. 6B is a profile for showing the concentration distribution of Mg contained in the p-type GaN layer 84 and the n-type GaN layer 85 shown in FIG. 8. Referring to FIGS. 6A and 6B, the axes of abscissas show positions of the devices in the thickness directions.

Referring to FIGS. 4 and 6A, the n⁻-type AlGaN layer 25 is formed on a portion of the n-type layered portion 22 in contact with the p-type GaN layer 21. As hereinabove described, the diffusion rate of Mg with respect to AlGaN is slow as compared with the diffusion rate with respect to GaN. Even if the p-type GaN layer 21 is doped with Mg in a high impurity concentration (1×10¹⁸ cm⁻³ to 5×10¹⁹ cm⁻³, for example), therefore, the Mg does not diffuse into the n⁺-type GaN layer 26 in the process of growth of GaN comprising the n⁺-type GaN layer 26. Therefore, the Mg concentration profile around the interface between the n-type layered portion 22 and the p-type GaN layer 21 can be steepened, as shown in FIG. 6A.

Referring to FIGS. 8 and 6B, on the other hand, Mg contained in the p-type GaN layer 84 diffuses into the n-type GaN layer 85 in the process of growth of GaN comprising the n-type GaN layer 85 in the conventional structure forming the n-type GaN layer 85 by growing the GaN to be in contact with the p-type GaN layer 84. Therefore, the Mg concentration profile around the interface between the n-type GaN layer 85 and the p-type GaN layer 84 is dull, as shown in FIG. 6B.

Thus, the n⁻-type AlGaN layer 25 is formed on the portion of the n-type layered portion 22 in contact with the p-type GaN layer 21 in the nitride semiconductor device according to the embodiment, whereby Mg can be inhibited from diffusing into the overall n-type layered portion 22 (more specifically, the n⁺-type GaN layer 26). Consequently, increase in the resistance of the overall n-type layered portion 22 can be suppressed.

While the embodiments of the present invention have been described, the present invention may be embodied in other ways.

For example, while the two nitride semiconductor devices having vertical npn structures have been described as the embodiments of the present invention, the present invention is not restricted to a nitride semiconductor device having a vertical npn structure, but is also applicable to another nitride semiconductor device, so far as the same has a p-n junction.

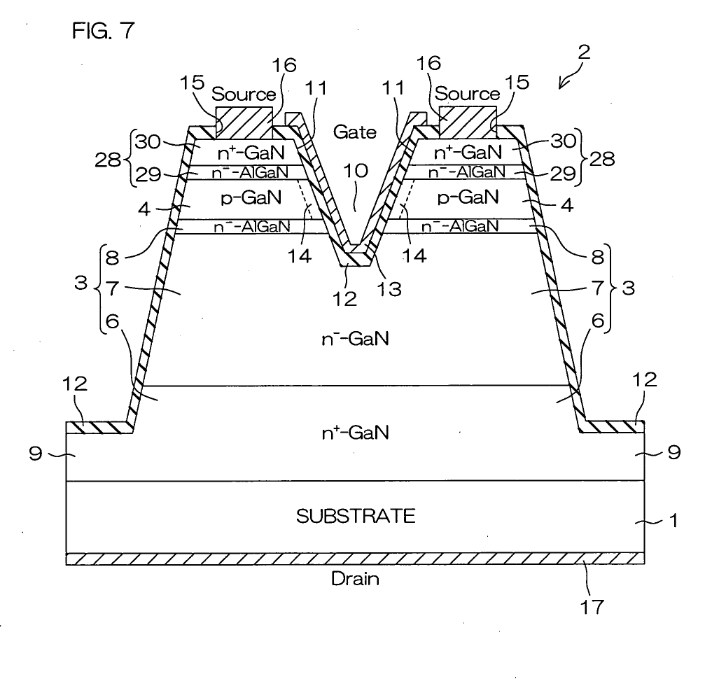

For example, the aforementioned first and second embodiments can be combined with each other. In other words, an n-type layered portion 28 consisting of an n⁻-type AlGaN layer 29 formed in contact with the p-type GaN layer 4 and an n⁺-type GaN layer 30 formed on the n⁻-type AlGaN layer 29 may be formed in place of the n⁺-type GaN layer 5 in the nitride semiconductor device shown in FIG. 1 (see FIG. 7). According to the structure, Mg concentration profiles around the interfaces between the p-type GaN layer 4 and the n-type layered portions 3 and 28 can be steepened. Therefore, generation of a leakage current in operation of the device can be suppressed by forming an excellent p-n junction between the n-type layered portion 3 and the p-type GaN layer 4, and increase in the resistance of the overall n-type layered portion 28 can also be suppressed.

While the n⁻-type AlGaN layer 8 containing Al is formed only on the portion of the n-type layered portion 3 in contact with the p-type GaN layer 4 in the aforementioned first embodiment, the overall n-type layered portion 3 may alternatively be made of AlGaN, for example. Also as to the aforementioned second embodiment, the overall n-type layered portion 22 may be made of AlGaN, for example. Similarly, the overall n-type layered portions 3 and 28 may be made of AlGaN also in a third embodiment shown in FIG. 7.

While MOCVD is applied as the method of growing GaN and AlGaN in each of the aforementioned embodiments, another growth method such as LPE (Liquid Phase Epitaxy), VPE (Vapor Phase Epitaxy), MBE (Molecular Beam Epitaxy), or the like, may alternatively be applied.

While the trench 10 having the generally V-shaped section is formed in the nitride semiconductor multilayer structure portion 2 in each of the aforementioned embodiments, the trench 10 may alternatively have another sectional shape such as an inverted trapezoidal shape, a U-shape, a rectangular shape or a trapezoidal shape.

In the formation of the gate insulating film 12, regions around the side surfaces of the p-type GaN layer 4 or 21 may be altered by application of Ar⁺ plasma, so that the semiconductor surface portion of the p-type GaN layer 4 or 21 is formed by a altered layer different in conductivity from the p-type GaN layer 4 or 21, for example. In this case, the gate insulating film 12 can be formed in contact with the altered layer. Thus, the gate threshold voltage can be reduced, and electron mobility can be improved. Consequently, on-resistance can be reduced, and an excellent power device can be implemented.

The wall surfaces 11, inclined with respect to the substrate 1 in each of the aforementioned embodiments, may be neither inclined nor planar. In other words, the wall surfaces 11 may be planes perpendicular to the substrate 1, or may be curved surfaces.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2008-56750 filed with the Japanese Patent Office on Mar. 6, 2008, the disclosure of which is incorporated herein by reference.

What is claimed is:

1. A nitride semiconductor device comprising:
an n-type layer made of a group III nitride semiconductor; and
a layer made of a group III nitride semiconductor containing a p-type impurity laminated and formed in contact with the n-type layer, wherein
Al is contained in a portion of the n-type layer in contact with the layer containing the p-type impurity.

2. A nitride semiconductor device comprising:
a first layer made of an n-type group III nitride semiconductor;
a second layer made of a group III nitride semiconductor containing a p-type impurity laminated and formed in contact with the first layer; and
a third layer made of an n-type group III nitride semiconductor laminated and formed on the second layer, wherein
Al is contained in a portion of the first layer in contact with the second layer.

3. A nitride semiconductor device comprising:
a first layer made of an n-type group III nitride semiconductor;
a second layer made of a group III nitride semiconductor containing a p-type impurity laminated and formed on the first layer; and
a third layer made of an n-type group III nitride semiconductor laminated and formed in contact with the second layer, wherein
Al is contained in a portion of the third layer in contact with the second layer.

4. A nitride semiconductor device comprising:
a first layer made of an n-type group III nitride semiconductor;
a second layer made of a group III nitride semiconductor containing a p-type impurity laminated and formed in contact with the first layer; and
a third layer made of an n-type group III nitride semiconductor laminated and formed in contact with the second layer, wherein
Al is contained in portions of the first layer and the third layer in contact with the second layer.
